(19) United States
(12) Patent Application Publication
(10) Pub. No.: US 2003/0183120 A1
(43) Pub. Date: Oct. 2, 2003

(54) Electroless copper plating solution, the electroless copper plating supplementary solution, and the method of manufacturing wiring board

(76) Inventors: Takeyuki Itabashi, Hitachi (JP); Haruo Akahoshi, Hitachi (JP); Hiroshi Kanemoto, Hitachi (JP); Tadashi Iida, Atsugi (JP); Naoki Nishimura, Yokohama (JP); Junichi Kawasaki, Yokohama (JP)

Correspondence Address: DICKSTEIN SHAPIRO MORIN & OSHINSKY LLP, 2101 L STREET NW, WASHINGTON, DC, 20037-1526, US

(21) Appl. No.: 10/078,445

(22) Filed: Feb. 21, 2002

(30) Foreign Application Priority Data
Nov. 15, 2001 (JP) 2001-349865

(51) Int. Cl. C23C 20/00; G03F 7/00

(52) U.S. Cl. 106/1.13; 430/314; 430/318

(57) ABSTRACT

An object of the present invention is to provide an elecroless copper plating solution using glyoxylic acid or a salt of glyoxylic acid as the reducing agent in which the amount of Cannizzaro reaction product is small, and the mechanical property of the obtained plated film is excellent, and to provide a supplementary solution for the electroless copper plating solution, a plating method capable of stably forming a plated film using the electroless copper plating solution, and a method of manufacturing a wiring board having an excellent connecting reliability of a through hole.

The present invention consist of an electroless copper plating solution including copper ions, a complexing agent of copper ion, a copper ion reducing agent containing glyoxylic acid or a salt of glyoxylic acid, a pH adjusting agent, and succinic acid; a supplementary solution for an electroless copper plating solution including a copper ion reducing agent containing glyoxylic acid or a salt of glyoxylic acid and succinic acid of 10 to 500 ppm; and an electroless copper plating method and a method of manufacturing a wiring board using the electroless copper plating solution and the supplementary solution.

### BACKGROUND OF THE INVENTION

1. Field of the Invention

The present invention relates to an electroless copper plating solution used for mainly forming wiring of an electronic device, and the supplementary solution and a method of forming a wiring board, and particularly to an electroless plating solution and the technology in which glyoxylic acid is used as the reducing agent of copper ion, but formaldehyde having high volatility is not used.

2. Prior Art

An electroless copper plating solution contains copper ions, a complexing agent of copper ion, a reducing agent of copper ion, and a pH adjusting agent. As the reducing agent of copper ion, formaldehyde or glyoxylic acid and a salt of glyoxylic acid are used. In the former case, formic acid ions are accumulated in the plating solution as the complex ions of the reducing agent. In the latter case, oxalic acid ions are accumulated in the plating solution.

Further, although sodium hydroxide (NaOH) is generally used as the pH adjusting agent, deposition of sodium oxalate occurs in the plating solution because solubility of sodium oxalate is small when glyoxylic acid is used as the reducing agent. If such solid deposit is attached onto the object to be plated, the plating material can not attach on the portion where the solid deposit attaches, and a “void” is formed. Therefore, as the countermeasure, Japanese Patent Application Laid-Open No.7-268638 discloses a method in which plating is performed while the plating solution is being filtered.

Japanese Patent Application Laid-Open No.61-183474 discloses that NaOH or KOH is used in order to alkalinize pH of an electroless copper plating solution using glyoxylic acid as the reducing agent, and that it is preferable to use KOH because solubility of oxalate of oxidant of glyoxylic acid is larger in potassium oxalate than in sodium oxalate.

Further, in a case of using glyoxylic acid, one of the reasons why oxalic acid accumulates in the plating solution is occurrence of Cannizzaro reaction in addition to the plating reaction.

The Cannizzaro reaction in the case of using glyoxylic acid is as follows.

2 CHOCOOH+2 OH→C₂O₄²⁻ +HOCH₂COOH+H₂O

By the above reaction, oxalic acid and glycolic acid are accumulated in the plating solution. Since the reaction rate of the above reaction becomes faster as temperature of the plating solution is increased, the Cannizzaro reaction can be suppressed by controlling the temperature of the plating solution to a low temperature.

Japanese Patent Application Laid-Open No.2000-144438 discloses a plating apparatus comprising a chamber for performing plating; and a circulation vessel for circulating a plating solution, wherein the solution temperature in the circulation vessel always storing the plating solution is maintained at a low temperature to suppress occurrence of the Cannizzaro reaction.

Further, it is described in “Surface Technology, Vol.42, No.9, 913-917 (1991)” and “Proceeding of the 6th Technical Meeting of the Society of Print Circuit Mounting, pp.101˜102” that when KOH is used as the pH adjusting agent for the electroless copper plating solution using glyoxylic acid glyoxylic acid as the reducing agent, the Cannizzaro reaction can be suppressed compared to when NaOH is used.

On the other hand, in the field of the electroless copper plating, various kinds of addition agents are added to the plating solution in order to improve stability of the plating solution and properties of the plating solution, and to improve connection reliability of the wiring of a printed wiring board.

For example, Japanese Patent Application Laid-Open No.51-105932 discloses an electroless copper plating solution containing the addition agents of at least one kind of 2,2′-bipyridyl, 2-(2-pyridyl)benzimidazol and 2,2′-diquinolyl, and polyalkylene glycol; and/or at least one kind of 1,10-phenanthrolynes and polyalkylene glycol. Japanese Patent Application Laid-Open No.2001-152353 discloses an electroless copper plating solution containing at least one kind of polyvalent alcohol compounds selected from the group consisting of ethylene glycol, glycerin and erythritol.

In the case of using glyoxylic acid as the reducing agent of the electroless copper plating solution, the plating solution is unstable because the Cannizzaro reaction is apt to occur compared to the case of using formaldehyde, and the cost becomes higher.

The meaning that the plating solution is stable is a state that the plating reaction is hardly progressed on surfaces except a surface to be plated. In this case, the state is that the surface to be plated of a product can be essentially plated without depositing of copper onto the wall surface of the plating bath in contact with the plating solution, and precipitation of copper powder or copper oxide powder to the bottom of the plating bath is hardly occurs.

On the other hand, the meaning that the plating solution is unstable is a state that copper is deposited onto the wall surface of the plating bath and the bottom surface of the plating bath, that is, copper is deposited onto the portions other than the surface to be plated of the product, and that when the situation is further progressed, almost all of the copper ions in the plating solution are precipitated in the plating bath as copper powder or copper oxide powder.

In regard to the decrease of the stability of the plating solution, the considerable cause is that because the amount of Cannizzaro reaction is large to increase the density of salt in the plating solution, the concentration of dissolved oxygen in the plating solution is decreased to reduce the stability of the plating solution.

Further, in the case of using glyoxylic acid, oxalic acid of oxide material of glyoxylic acid is accumulated in the plating solution due to the Cannizzaro reaction Cannizzaro reaction or the plating reaction. Although the electroless copper plating is generally performed while NaOH is being added in order to maintain the alkalinity of the plating solution, there has been a problem in that crystals of sodium oxalate precipitates in the plating solution because of the solubility of sodium oxalate is small, and plating does deposited on a board to form a void when the crystals of sodium oxalate are attached onto the board. In order to prevent increasing of the salt concentration in the plating solution and to prevent the forming of precipitation of sodium oxalate as described above, a method of using KOH as a pH adjusting agent to be added to the plating solution during plating to maintain the alkalinity of the plating solution has been studied. However, in a case where a conductor of a wiring board is formed using a plating solution in which KOH is used as the pH adjusting agent and glyoxylic acid is used as the reducing agent, there has been a problem in that reliability of connecting a through hole is degraded compared to a case where a conductor of a wiring board is formed using a plating solution in which NaOH is used as the pH adjusting agent and formaldehyde is used as the reducing agent. The reliability of connecting a through hole is to be described later.

### SUMMARY OF THE INVENTION

An object of the present invention is to provide an electroless copper plating solution using glyoxylic acid or a salt of glyoxylic acid as the reducing agent in which the amount of Cannizzaro reaction product is small, and the mechanical property of the obtained plated film is excellent.

Another object of the present invention is to provide a supplementary solution for an electroless copper plating solution which makes it possible to suppress the Cannizzaro reaction in the elecroless copper plating solution using glyoxylic acid or a salt of glyoxylic acid as the reducing agent, and to obtain a plated film having an excellent mechanical property.

A further object of the present invention is to provide a plating method which can stably form a plated film by the electroless copper plating solution using glyoxylic acid or a salt of glyoxylic acid as the reducing agent.

A still further object of the present invention is to provide a method of manufacturing a wiring board having excellent connection reliability of a through hole or a via hole by the electroless copper plating solution using glyoxylic acid or a salt of glyoxylic acid as the reducing agent.

Summaries of the present invention are as follows.

1. An electroless copper plating solution including copper ions, a complexing agent of copper ion, a copper ion reducing agent, a pH adjusting agent and succinic acid, wherein the copper ion reducing agent is glyoxylic acid or a salt of glyoxylic acid, and the elecroless copper plating solution is an electroless copper plating solution containing succinic acid. It is preferable the electroless copper plating solution containing succinic acid of 0.1 to 1000 ppm.

2. A supplementary solution for an electroless copper plating solution to supplement glyoxylic acid to the electroless copper plating solution including a copper ion reducing agent containing glyoxylic acid or a salt of glyoxylic acid, wherein the supplementary solution for the electroless copper plating solution is a supplementary solution for the elecroless copper plating solution contains succinic acid of 10 to 500 ppm.

3. A plating method comprising a process of forming a copper film on a surface of a board by performing electroless copper plating process using the electroless copper plating solution described above.

4. A plating method comprising a process of forming a copper film on a surface of a board by performing electroless copper plating process using the supplementary solution for the electroless copper plating solution described above.

5. A method of manufacturing a wiring board by forming a conductor film on a surface of a board using the electroless copper plating solution described above.

6. A method of forming a wiring board, the method comprising the steps of forming a through hole in a copper-clad laminate having a laminated copper film on a surface of at least one side of main faces of a base material; adding a catalyst onto an inner wall surface of the through hole; forming a copper film in the through hole of the board formed in the above step by performing an electroless copper plating using the electroless copper plating solution described above; forming an etching resist over the whole surface of the board obtained in the above step, and forming an etching resist wiring pattern by an exposing and developing process; and forming a copper film wiring pattern by dissolving and removing the exposed copper film in the above step.

7. A method of forming a wiring board, the method comprising the steps of forming a through hole in a double-sided copper-clad laminate; adding a catalyst onto an inner wall surface of said through hole using a sensitization processing agent and a adhesion promotion processing agent; forming a copper film in the through hole of the board formed in the above step by performing an electroless copper plating using the electroless copper plating solution described above; forming an etching resist of a photosensitive dry-film type over the whole surface of the board obtained in the above step, and forming an etching resist wiring pattern by an exposing and developing process; and forming a copper film wiring pattern by dissolving and removing the exposed copper film in the above step.

8. A method of forming a wiring board, the method comprising the steps of forming a through hole in a copper-clad laminate having a laminated copper film on a surface of at least one side of main faces of a base material; adding a catalyst onto an inner wall surface of said through hole; forming a copper film in the through hole of the board formed in the above step by performing an electroless copper plating while the supplementary solution for the electroless copper plating solution described above is being supplied to the electroless copper plating solution described above; forming an etching resist over the whole surface of the board obtained in the above step, and forming an etching resist wiring pattern by an exposing and developing process; and forming a copper film wiring pattern by dissolving and removing the exposed copper film in the above step.

A method of forming a wiring board, the method comprising the steps of forming a through hole in a double-sided copper-clad laminate; adding a catalyst onto an inner wall surface of the through hole using a sensitization processing agent and a adhesion promotion processing agent; forming a copper film in the through hole of the board formed in the above step by performing an electroless copper plating while the supplementary solution for the electroless copper plating solution described above to the electroless copper plating solution described above; forming an etching resist of a photosensitive dry-film type over the whole surface of the board obtained in the above step, and forming an etching resist wiring pattern by an exposing and developing process; and forming a copper film wiring pattern by dissolving and removing the exposed copper film in the above step.

10. A method of manufacturing a wiring board, the method comprising the steps of forming a copper film on a surface of a board using the electroless copper plating solution described above; and then performing electroplating using the copper film as an electric power supply film.

11. A method of manufacturing a wiring board, the method comprising the steps of forming a copper film on a surface of a board while the supplementary solution for an electroless copper plating solution is being supplied to the electroless copper plating solution; and then performing electroplating using the copper film as an electric power supply film.

According to the present invention, by adding succinic acid to the electroless copper plating solution containing glyoxylic acid as the reducing agent, it is possible to provide the electroless copper plating solution having an excellent property of uniformly depositing copper plating to a through hole in a wiring board, and further to provide a wiring board having good connection reliability of a through hole.

The electroless copper plating reaction using the electroless copper plating solution containing glyoxylic acid as the reducing agent and ethylene-diamine tetra-acetic acid (EDTA) as the complexing agent can be expressed by the following reaction formula.

Cu²⁺ (EDTA)⁴⁻ +2 CHOCOO⁻ +4 OH→Cu+2 (COO)₂²⁻ +2 H₂O+EDTA⁴⁻

As the plating reaction is progressed, oxalate ions are accumulated in the plating solution. Further, since the plating solution is an alkaline aqueous solution, the Cannizzaro reaction shown by the following reaction formula is progressed to accumulate oxalate ions and glyoxylate acid ions in the electroless copper plating solution.

2 CHOCOO⁻ +OH⁻ →(COO)₂²⁻ +CH₂OHCOO⁻

Since the solubility of sodium oxalate is small, there occurs a problem in that crystals of sodium oxalate are deposited and precipitated in the plating solution. On the other hand, the solubility of potassium oxalate is larger compared to the solubility of sodium oxalate.

Therefore, generation of oxalate can be suppressed by KOH for the pH adjusting agent of a composition of the electroless copper plating solution and by using potassium salts including EDTA to make the plating solution sodium free.

However, in the case where the wiring of a wiring board is formed by the plating solution using KOH as the pH adjusting agent and glyoxilic acid as the reducing agent, the connection reliability of a through hole is worse compared to that in the conventional case of using formaldehyde as the reducing agent and NaOH as the pH adjusting agent.

According a result experimentally obtained by the inventors of the present invention, in a plating solution of which the sodium concentration contained in the plating solution was decreased lower than 100 ppm by using KOH, precipitation of oxalate appeared when the concentration of oxalic acid became about 6 mol/L. As the result, the plating solution became unstable, and copper started to be deposited onto the wall surface of the plating bath and onto the inside of a pipe circulating the plating solution other than the surface of an object to be plated. Thus, the plating solution could not be used further more.

The concentration of oxalic acid producing precipitation of oxalate, that is, the concentration of oxalic acid making the plating solution unstable was different depending on the composition of the plating solution and the plating condition, but it was estimated to be 0.5 to 0.8 mol/L. In the present specification, the time when the precipitation of oxalate is started, that is, when the plating solution becomes unstable is expressed as the lifetime of the plating solution. Assuming that the time when oxalic acid ions of 0.6 mol/L are accumulated is defined as the lifetime of the plating solution, and that all the glyoxylic acid is consumed in the plating reaction without causing the Cannizzaro reaction, an amount of copper deposited as the plated film per 1 liter plating solution is 0.3 mol/L.

This is because from the reaction formula described above, glyoxylic acid of 2 mol/L is the reaction equivalent to copper ion 1 mol/L. This is the amount corresponding to copper plate thickness of 100 ìm when the plating bath load is assumed to be 2 dm²/L.

However, there was a problem in that plate thickness actually obtained was only about 30 ìm because the Cannizzaro reaction was progressed to produce oxalic acid. This is because the Cannizzaro reaction is progressed in the plating solution to produce oxalic acid by a reaction other than the plating reaction. The Cannizzaro reaction not only shortens the lifetime of the plating solution but also increases the cost of the plating process. Therefore, the additive for adding to the plating solution for various kinds of purposes must not promote the Cannizzaro reaction, and on the contrary, preferably suppresses the Cannizzaro reaction.

Therein, oxalic acid is always produced as far as glyoxylic acid is used, and the saturation solubility of oxalic acid to the plating solution is determined by the composition of the plating solution. The amount is about 0.5 to 0.8 mol/L.

On the other hand, mechanical properties (ductility of film, tensile strength and so on) of the plated film obtained by the electroless plating substantially depend on kind and concentration of a substance to be added to the plating solution (additive). In a case of using the electroless copper plating for forming wiring of a wiring board, the mechanical properties of the plated film are very important elements because the mechanical properties strongly influence on the reliability of the wiring board. That is, when a conductor is formed by a plated film having a large ductility, the wiring board is formed to a highly reliable wiring board which is strong against thermal shock such as temperature cycle, and strong to a heating process such as a soldering process. Reliability against thermal shock, bending stress and so on is very important to the wiring board, and a plating technology can not be applied when the plating technology does not satisfy a necessary requiring property. Particularly, a plated film formed in a through hole portion formed in a board for connecting between layers influences the reliability of the wiring board because stress concentrates on the plated film due to its shape. Therefore, the reliability of the wiring board can be regarded to be equivalent to the connecting reliability of the through hole portion by the plated film. Thereafter, the reliability of the wiring board is evaluated by the connecting reliability of the through hole.

Although various kinds of additives to improve reliability of a wiring board have been disclosed, these additives are on the premise that formaldehyde is used as the reducing agent and NaOH is used as the pH adjusting agent. In the case of using glyoxylic acid as the reducing agent, the connecting reliability of a through hole is lower compared to in the case of using formaldehyde as the reducing agent as described above.

In the present invention, in the case of using glyoxylic acid as the reducing agent, succinic acid is provided as an additive which makes the physical properties of an obtained plated film good, and improves the connecting reliability of a through hole of a wiring board, and further, suppresses the Cannizzaro reaction in the plating solution.

The physical properties of the plated film obtained from the plating solution added with succinic acid in accordance with the present invention are nearly equal to those in the case without succinic acid. In this case, the physical properties of the plated film are nearly equal to physical properties of a film obtained using a plating solution added with a single other additive added to the plating solution at the same time, for example, well-known 2,2′-bipyridyl, polyethylene glycol, 1,10-phenanthroline or the like. The physical properties of the plated film are determined by an additive other than succinic acid.

In the case where the plating solution added with succinic acid is applied to forming of wiring of a wiring board, the connecting reliability of through hole of the wiring board is remarkably improved. The improvement of the reliability by adding succinic acid is caused by an effect of improvement in uniformity of deposition to the inner wall surface of the through hole at the initial stage of plating deposition.

There is a method of forming wiring of a wiring board in which a thin plated film having a film thickness smaller than 1 μm is formed on a board through electroless copper plating, and then a conductor having a desired thickness is formed by performing electroplating using the copper plated film obtained by the electroless copper plating as the power supply film.

The electroless copper plating technology used as described above is, hereinafter, referred to as a seeding electroless copper plating technology as the seeding layer for the electroplating. On the other hand, there is a method of forming a copper film having a film thickness of several μm to several tens μm through electroless copper plating, and this method is to be referred as full build electroless copper plating.

In the seeding electroless copper plating technology, the deposition uniformity is one of the most important characteristics because the purpose of the seeding electroless copper plating is to form the power supply film to be used in the following electroplating. Particularly, the deposition uniformity to the inner wall surface of the through hole is important in the wiring board. Therefore, the electroless copper plating solution added with succinic acid is effective for the seeding electroless copper plating solution because of the good deposition uniformity.

The electroless copper plating solutions for both of the full build electroless copper plating and the seeding electroless copper plating can be obtained by adding succinic acid to the conventionally used plating solution. For example, description will be made below on a case where the following plating solution has been conventionally used. (Composition of the conventional plating solution (I))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |

Therein, the concentration of potassium hydroxide is appropriately adjusted so as to satisfy the condition of pH=12.4.

(Conventional plating condition (I))

| | |
|---|---|
| pH | 12.4 |
| temperature of solution | 70° C. |

Therein, according to the present invention, the plating solution having the following composition can be obtained by adding succinic acid by 5 ppm. (Composition of the plating solution according to the present invention (I))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |
| succinic acid | 5 | mg/L |

Therein, the concentration of potassium hydroxide is appropriately adjusted so as to satisfy the condition of pH=12.4.

(Plating condition according to the present invention (I))

| | |
|---|---|
| pH | 12.4 |
| temperature of solution | 70° C. |

The composition of the plating solution according to the present invention is obtained by adding succinic acid to the composition of the conventional plating solution. The plating rate, the physical properties of the plated film obtained, and the other characteristics in this case are little changed from those in the conventional case. The above-described characteristics are seemed to be determined by 2,2′-bipyridyl and polyethylene glycol which have been added to the plating solution in advance. Succinic acid does not deteriorate the effects of 2,2′-bipyridyl and polyethylene glycol which improve the plating rate, the physical properties of the plated film obtained, and the other characteristics.

On the other hand, the amount of Cannizzaro reaction during plating is about 90% of the amount in the conventional case. That is, by the above plating solution according to the present invention, the effect of reducing the Cannizzaro reaction by 10% can be attained.

Further, in the case of forming a conductor of a wiring board using the plating solution according to the present invention, the connecting reliability of through hole is remarkably improved compared to the case of using the conventional plating solution not containing succinic acid. Although cracks occur in the conductor when the wiring board is received thermal shocks, the lifetime against the thermal shocks until the cracks occur is lengthened by two times or more by adding succinic acid.

In regard to the method of adding succinic acid, succinic acid ma be added to the plating solution in advance, or succinic acid may be added to the aqueous solution of glyoxylic acid of the copper ion reducing agent. By adding succinic acid to the aqueous solution of glyoxylic acid in advance, the effect of suppressing the Cannizzaro reaction can be improved. Further, the adding amount of succinic acid has a wide margin to the reliability of the wiring board and to the physical properties of the obtained plated film.

Therefore, there is no need to analyze and control the composition of the plating solution in detail. Change in the concentration of succinic acid in the plating solution is caused only by taking out the plating solution remaining on the surface of a plated object such as a wiring board together with the wiring board when the plated object is taken out from the plating solution.

Therefore, a certain amount of succinic acid should be added to the plating solution corresponding to a processed amount of the plated objects. Since the reducing agent of glyoxylic acid is also added to the plating solution corresponding to the processed amount of the plated objects, succinic acid is not necessary to be separately added to the plating solution if succinic acid is added to the aqueous solution of glyoxylic acid in advance. Further, as previously described, the effect of suppressing the Cannizzaro reaction can be slightly increased by adding succinic acid to the aqueous solution of glyoxylic acid. Therefore, it is very effective to use the aqueous solution of glyoxylic acid containing succinic acid as the supplementary solution for the electroless copper plating solution.

The details of the above-described test methods and the details of the results will be described in the following embodiments.

### DESCRIPTION OF THE PREFERRED EMBODIMENTS

The present invention will be described below, referring to the following embodiments. Comparative examples indicate conventional electroless copper plating solutions and electroless copper plating technologies. Evaluation results are summarized and shown in Table 1.

[Embodiment 1]

A plating solution composition is prepared using copper sulfide as a copper ion source, ethylenediamin tetra-acetate as a complexing agent, glyoxylic acid as a copper ion reducing agent, and potassium hydroxide as a pH adjusting agent. Further, the flowing plating solution (II) is obtained by adding succinic acid to the plating solution. (Composition of the plating solution (II))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |
| succinic acid | 50 | mg/L |

Therein, the concentration of potassium hydroxide is appropriately adjusted so as to satisfy the condition of pH=12.4. Further, the plating conditions are the same as the plating conditions according to the present invention (I) previously described.

Using the above plating solution (II), a pattern was formed on a test board through electroless copper plating, and the lifetime of the plating solution and the quality of the plated film were evaluated from presence and absence of abnormal deposition of copper.

Further, an amount of oxalic acid ions and an amount of glycolic acid ions were quantitatively measured to calculate an amount of the Cannizzaro reaction. The method of forming the test board and the method of evaluating the physical properties of the plated film are as follows.

<Method of forming the test board>

A double-sided wiring board was formed through the following processes.

A though hole of ø0.3 mm diameter was formed through drill machining in a double-sided copper-clad laminate having copper film of 18 μm thick on the both surfaces of a glass-epoxy board of 1.6 mm thick. Shavings produced at the drill machining were removed using an alkali potassium permanganate aqueous.

After that, a catalyst was added onto the inner wall surface of the through hole described above using a cleaner-conditioner (trade name: CLC-601), a pre-dip (trade name: PD301), a sensitization processing agent (trade name: HS-202B) and an adhesion promotion processing agent (trade name: ADP-601).

Electroless copper plating treatment was performed to the board using the plating solution in accordance with the present invention. The thickness of obtained electroless plated film was set to 20 μm when the copper film for connecting the through hole was formed only by the electroless copper plating of the present embodiment, and was set to 0.3 μm when the copper film for connecting the through hole was formed by electroplating after the electroless copper plating of the present embodiment.

Therein, when the copper film for connecting the through hole was formed by electroplating after the electroless copper plating of the present embodiment, the thickness of electroplated film was set to 20 μm.

After forming the copper film of 20 μm through the electroless copper plating or the electroplating, an etching resist of photosensitive dry film type was formed over the whole surface of the board, and the wiring pattern portion was covered with an etching resist through exposing and developing treatment. The exposed copper film was solved and removed using a copper etching solution containing major compositions of sulfuric acid and hydrogen peroxide.

The width of the wire formed as described above was 100 ìm, and the through holes were aligned to form a through-hole chain composed of 500 through holes connected in a chain shape.

The test board formed as described above and a stainless steel plate were immersed together into the plating solution at a time, and performed with electroless copper plating at a bath load of 1 dm²/L which expresses an area to be plated per a volume of the plating solution of 1 L.

The stainless steel plate was used by dipping into a 17% aqueous solution of hydrochloric acid for 2 minutes, and washing with water after dipping into a sensitization processing solution for 10 minutes, and then washing with water after performing adhesion promotion processing for 3 minutes.

During plating, the plating solution was always stirred by blowing air into the plating bath. The supplemental solutions were supplied whenever necessary so that the concentration of copper ion, the concentration of glyoxylic acid (copper ion reducing agent) and the pH during plating were within the respective ranges. The composition of each of the supplemental solutions is as follows.

(1) copper ion supplemental solution CuSO₄·5H₂O: 200 g water: an amount required to make the solution 1 L

(2) glyoxylic acid (copper ion reducing agent) supplemental solution 40% glyoxylic acid solution

(3) pH adjusting agent KOH: 40 g water: an amount required to make the solution 1 L

One cycle of the plating was defined that copper was plated by an amount corresponding to a thickness of 30 μm onto the stainless steel plate or the pattern portion of the test board. Every time when each of the cycle of the plating was completed, a plated film was pealed from the stainless steel plate, and the pealed plated film was cut into a piece having size 1.25 cm×10 cm to measure the mechanical strength of the plated film using a tensile test machine.

(a) Measurement of an amount of the Cannizzaro reaction Measurement of an amount of the Cannizzaro reaction was performed by sampling the plating solution, and then quantitatively measuring an amount of oxalic acid and an amount of glycolic acid in the sampled plating solution through the ion chromatography method.

The oxalic acid is produced by the plating reaction and by the Cannizzaro reaction, and the glycolic acid is produced only by the Cannizzaro reaction. Therefore, the amount of glycolic acid in the plating solution corresponds to the amount of the Cannizzaro reaction. Two times of the measured molar amount of glycolic acid corresponds to an amount of glyoxylic acid consumed by the Cannizzaro reaction.

A ratio of the Cannizzaro reaction is the amount of glyoxylic acid consumed by the Cannizzaro reaction divided by the total amount of glyoxylic acid, and can be calculated by the following equation.

Ratio of the Cannizzaro reaction=Amount of the Cannizzaro reaction/(Amount of the Cannizzaro reaction+Amount of deposited copper at end of lifetime×2)

Judgment of the lifetime of the plating solution was determined by the time when copper started to be deposited on a portion other than the board to be plated in the above-mentioned test.

The deposition rate of the plating solution used in the present embodiment was 3.1 μm/h, and the time required for depositing copper by 30 μm thickness was about 10 hours.

Next, the mechanical properties of the plated film were measured. As the result of the tensile test, the elongation was 20.5%, and the tensile strength was 320 MPa, which showed very good physical properties of the plated film. These properties of the plated film indicate that the plating solution is sufficiently applicable for the full build electroless copper plating solution.

<Connection reliability of through hole>

Using the above-described test board, the connection reliability of the through hole in the case of applying the plating solution (II) to the wiring board was evaluated through the following thermal shock test and the following solder heating resistance test.

(b) Thermal shock test

One cycle of the thermal shock test was defined by that the board was kept at a temperature of −65° C. for 120 minutes, and then returned to and kept at room temperature for 5 minutes, and after that, kept at +125° C. for 120 minutes. Judgment of the lifetime for the thermal shock test was determined by the number of the cycles that the electric resistance of the through-hole chain composed of 500 through holes connected in a chain shape in the test board was increased by 10% of the initial resistance.

(c) Solder heating resistance test

One cycle of the solder heating resistance test was defined by that the test board was dipped into a molten solder bath of 280° C. for 10 seconds, and then taken out. After 5 cycles of the solder heating resistance test, the test board was embedded in an embedding resin for section observing (a product of Viewer Co.: Epomix), and the through hole sectional portion was cut out to observe the 30 through holes using a microscope. The observed section of the sample was mirror-finished, and the copper was soft-etched by an etching solution containing sulfuric acid and hydrogen peroxide in order to remove burrs produced at polishing. Judgment of the good condition of the solder heating resistance was determined by a case where no crack occurred in the sections of the 30 though holes.

In the thermal shock test of the test board having the copper film formed using the plating solution (II) of the present embodiment, the number of the cycles that the electric resistance of the through-hole chain was increased by 10% of the initial resistance was after 350 cycles, and the result was good. Further, no crack occurred in the sections of the 30 though holes.

From the above results, the test board shows good connecting reliability of the through hole, and the plating solution (II) of the present embodiment has a sufficient function as the electroless copper plating solution.

The Cannizzaro reaction in the electroless copper plating solution of the present embodiment will be described below. Copper started to be deposited onto a portion other than the board to be plated was at the time when the amount of deposited copper reached 0.23 mol/L. Therefore, judgment of the lifetime of the plating solution was determined as the time when the amount of deposited copper reached 0.23 mol/L. Further, an amount of glycolic acid in the plating solution reaching the lifetime was measured, and as the result, it was found that the amount of glycolic acid was 0.03 mol/L. Accordingly, the amount of glyoxylic acid consumed by the Cannizzaro reaction was 0.06 mol/L.

The amount of glyoxylic acid reacted to deposit copper of 0.23 mol/L is 0.46 mol/L, and the amount of glyoxylic acid consumed by the Cannizzaro reaction was 0.06 mol/L. Therefore, the ratio of the amount of glyoxylic acid consumed by the Cannizzaro reaction was 0.06 mol/L was about 11.5% of the total amount of glyoxylic acid.

As described above, in the plating solution in accordance with the present invention, the ratio of the amount of glyoxylic acid consumed by the Cannizzaro reaction was 0.06 mol/L was as small as about 11.5%, and the amount of copper per 1 L of plating solution capable of being deposited within the lifetime was as much as 0.23 mol/L. Therefore, it is verified that the plating solution (II) containing succinic acid has the effect of suppressing the Cannizzaro reaction.

[Embodiment 2]

Copper sulfide was used as the copper ion source, ethylenediamin tetra-acetate was used as the complexing agent, glyoxylic acid was used as the copper ion reducing agent, and potassium hydroxide was used as the pH adjusting agent. Further, succinic acid was added to the plating solution. The plating rate was decreased by lowering temperature of the plating solution to evaluate the plating solution as the seeding electroless copper plating solution.

The composition of the plating solution and the plating condition are as follows.

(Composition of the plating solution (III))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |
| succinic acid | 50 | mg/L |

Therein, the concentration of potassium hydroxide is appropriately adjusted so as to satisfy the condition of pH=12.4. Further, temperature of the plating solution is set to 30° C., and the other plating conditions are the same as the plating conditions according to the present invention (I) previously described.

The solder heating resistance test for the seeding plating was conducted by performing electric copper plating (film thickness was 25 μm) to a test board having plating film of 0.1 to 1.0 μm thick, and by observing presence or absence of occurrence of cracks when the solder heating resistance test described previously was performed on the obtained test board. When cracks are not observed, the word “good” is marked in the column of solder heating resistance test for the seeding plating in Table 1 to be described later. When cracks are observed, the word “no good” is marked in the column of solder heating resistance test for the seeding plating in Table 1.

<Electric copper plating solution>

| | | |
|---|---|---|
| copper sulfide 5-hydrate | 0.3 | mol/L |
| sulfuric acid | 1.9 | mol/L |
| chlorine ions | 60 | mg/L |
| additive(a product of Kamimura Industry Co.: | 5 | mL/L |
| Sulcup AC-90) | | |

<Conditions of the plating>

| | |
|---|---|
| temperature of the plating solution | 25° C. |
| cathode current density | 30 mA/cm² |
| stirring | air stirring |

In the thermal shock test of the test board having a copper film of about 25 μm thick formed using the above-described electric copper plating solution after forming the copper film of about 0.3 μm thick using the electroless copper plating solution of the present embodiment, the number of the cycles that the electric resistance of the through-hole chain was increased by 10% of the initial resistance was after 300 cycles, and accordingly the result was good. Further, no crack was observed after the solder heating resistance test either.

From the above results, it can be verified that the test board formed in the present embodiment has good connecting reliability of the through hole, and that the plating solution of the present embodiment has a sufficient function as the electroless copper plating solution for forming the base film for electroplating.

[Embodiment 3]

In this embodiment, the additive of succinic acid is not added to the plating solution, but succinic acid is added to an aqueous solution of glyoxylic acid used for supplementing the copper ion reducing agent of glyoxylic acid to the plating solution. The tests having the same test contents as the embodiment 1 were conducted.

The composition of the plating solution and the test condition, and the composition of the supplemental solution are as follows.

(Composition of the plating solution (IV))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |

Therein, the concentration of potassium hydroxide is appropriately adjusted so as to satisfy the condition of pH=12.4. Further, the plating conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution

| | |
|---|---|
| 40% glyoxylic acid solution | |
| succinic acid | 0.5 g/L |

(3) pH adjusting agent KOH: 40 g water: an amount required to make the solution 1 L

The glyoxylic acid (copper ion reducing agent) supplemental solution was prepared by adding succinic acid of 0.5 g to the 40% glyoxylic acid solution of 1 L.

The test board of the embodiment 1 and a stainless steel plate for measuring plated film measurement were immersed into the plating solution to continuously perform full build plating under a plating condition of 1 dm² /L plating bath load. As the result, 6 processes of the full build electroless copper plating forming a film of 30 μm could be repetitively performed. However, at the 7th process, the plating solution became unstable, and the plating could not be continued. At that time, the total amount of supplemented glyoxylic acid was about 0.6 mol/L.

The concentration of succinic acid in the plating solution was increase as the number of the repetitive plating processes was increased. The concentration was increased from the initial concentration of about 3 ppm up to about 60 ppm.

Table 1 shows the evaluation result of the connecting reliability of through hole of the test board obtained from plating in each of the plating processes. Good connecting reliability of the through hole was obtained in all of the board.

From the above results, it can be verified that the test board formed in the present embodiment has good connecting reliability of the through hole, and that the electroless copper plating solution of the present embodiment shows excellent through-hole connecting reliability when it is applied to forming of wiring of the wiring board, and that the plating solution of the present embodiment has a sufficient function as the electroless copper plating solution.

Further, at the same time, the result of the present embodiment shows that the succinic acid added to the plating solution has the effect of improving the reliability of the wiring board over the wide range of 3 to 60 ppm of the succinic acid concentration.

[Embodiment 4]

In this embodiment, the additive of succinic acid is not added to the plating solution, but succinic acid is added to an aqueous solution of glyoxylic acid used for supplementing the copper ion reducing agent of glyoxylic acid to the plating solution. The tests having the same test contents as the embodiment 1 were conducted.

The composition of the plating solution and the composition of the supplemental solution are as follows.

(Composition of the plating solution (V))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |

Therein, the concentration of potassium hydroxide is appropriately adjusted so as to satisfy the condition of pH=12.4. Further, the plating conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution

| | |
|---|---|
| 40% glyoxylic acid solution | |
| succinic acid | 30 mg/L |

(3) pH adjusting agent KOH: 40 g water: an amount required to make the solution 1 L

The glyoxylic acid (copper ion reducing agent) supplemental solution was prepared by adding succinic acid of 30 mg to the 40% glyoxylic acid solution of 1 L.

The test board described in the embodiment 1 and a stainless steel plate for measuring plated film measurement were immersed into the plating solution to continuously perform full build plating under a plating condition of 1 dm²/L plating bath load. As the result, 5 processes of the full build electroless copper plating forming a film of 30 ìm could be repetitively performed.

However, at the 6th process, the plating solution became unstable, and the plating could not be continued.

The reason why the number of repetitive plating processes in the present embodiment is reduced to 5 processes compared to that in the embodiment 3 is the average concentration of succinic acid in the plating solution is lower than that in the embodiment 3. At that time, the total amount of supplemented glyoxylic acid was about 0.6 mol/L.

The concentration of succinic acid in the plating solution after completion of each of the repetitive plating processes was increased from the initial concentration of about 0.1 ppm up to about 3.3 ppm.

Table 1 shows the evaluation result of the connecting reliability of through hole of the test board obtained from plating in each of the plating processes. Good connecting reliability of the through hole was obtained in all of the board.

From the above results, it can be verified that the test board formed in the present embodiment has good connecting reliability of the through hole, and that the electroless copper plating solution of the present embodiment shows excellent through-hole connecting reliability when it is applied to forming of wiring of the wiring board, and that the plating solution of the present embodiment has a sufficient function as the electroless copper plating solution.

Further, at the same time, the result of the present embodiment shows that the succinic acid added to the plating solution has the effect of improving the reliability of the wiring board over the wide range of 0.1 to 20 ppm of the succinic acid concentration.

[Embodiment 5]

In this embodiment, the additive of succinic acid is not added to the plating solution, but succinic acid is added to an aqueous solution of glyoxylic acid used for supplementing the copper ion reducing agent of glyoxylic acid to the plating solution. The tests having the same test contents as the embodiment 1 were conducted.

The composition of the plating solution and the composition of the supplemental solution are as follows.

(Composition of the plating solution (VI))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |

Therein, the concentration of potassium hydroxide is appropriately adjusted so as to satisfy the condition of pH=12.4. Further, the plating conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution

| | |
|---|---|
| 40% glyoxylic acid solution | |
| succinic acid | 9.0 g/L |

(3) pH adjusting agent KOH: 40 g film thickness is 25 μm water: an amount required to make the solution 1 L

The glyoxylic acid (copper ion reducing agent) supplemental solution was prepared by adding succinic acid of 9 g to the 40% glyoxylic acid solution of 1 L.

The test board described in the embodiment 1 and a stainless steel plate for measuring plated film measurement were immersed into the plating solution to continuously perform full build plating under a plating condition of 1 dm²/L plating bath load. As the result, 6 processes of the full build electroless copper plating forming a film of 30 μm could be repetitively performed. However, at the 7th process, the plating solution became unstable, and the plating could not be continued. At that time, the total amount of supplemented glyoxylic acid was about 0.6 mol/L.

The concentration of succinic acid in the plating solution after completion of each of the repetitive plating processes was increased from the initial concentration of about 50 ppm up to about 1000 ppm.

Table 1 shows the evaluation result of the connecting reliability of through hole of the test board obtained from plating in each of the plating processes. Good connecting reliability of the through hole was obtained in all of the board.

From the above results, it can be verified that the test board formed in the present embodiment has good connecting reliability of the through hole, and that the electroless copper plating solution of the present embodiment shows excellent through-hole connecting reliability when it is applied to forming of wiring of the wiring board, and that the plating solution of the present embodiment has a sufficient function as the electroless copper plating solution.

Further, at the same time, the result of the present embodiment shows that the succinic acid added to the plating solution has the effect of improving the reliability of the wiring board over the wide range of 50 to 1000 ppm of the succinic acid concentration.

[Embodiment 6]

Similar to the embodiments 3 to 5, this embodiment is a case where the additive of succinic acid is added to the aqueous solution of glyoxylic acid, and a case where the present invention is applied to the seeding electroless copper plating technology. The tests having the same test contents as the embodiment 2 were conducted.

The composition of the plating solution and the composition of the supplemental solution are as follows.

(Composition of the plating solution (VII))

| | | |
|---|---|---|
| copper sulfide 5-hydrate | 0.04 | mol/L |
| ethylenediamin tetra-acetate | 0.1 | mol/L |
| glyoxylic acid | 0.3 | mol/L |
| potassium hydroxide | 0.01 | mol/L |
| 2,2′-bipyridyl | 0.0002 | mol/L |
| polyethylene glycol (average molecular weight 600) | 0.03 | mol/L |

Therein, the concentration of potassium hydroxide is appropriately adjusted so as to satisfy the condition of pH=12.4. Further, the plating test condition of solution temperature is 25 to 30° C., and the other plating conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution

| | |
|---|---|
| 40% glyoxylic acid solution | |
| succinic acid | 30 mg/L |

(3) pH adjusting agent KOH: 40 g water: an amount required to make the solution 1 L

By adding succinic acid to the glyoxylic acid supplemental solution and by repetitively performing plating, the concentration of succinic acid in the plating solution was changed from about 1.6 to 1000 ppm.

Characteristics of the prototype board are shown in Table 1. The thermal shock test results were good for all the boards within the range of the succinic acid concentration. Further, there was no crack in the through hole portion even after the solder heating resistance test.

From the above results, it can be verified that the test board formed in the present embodiment has good connecting reliability of the through hole. Further, it was clarified that the electroless copper plating solution of the present embodiment has a sufficient function as the electroless copper plating solution for forming the base film for electroplating. Thus the effects of the present embodiment could be verified.

[Comparative example 1]

Description will be made below on a case where succinic acid is added to neither the plating solution nor the glyoxylic acid supplemental solution. The composition of the plating solution and the composition of the supplemental solution are as follows.

(Composition of the plating solution (Ia))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |

Therein, the concentration of potassium hydroxide is appropriately adjusted so as to satisfy the condition of pH=12.4. Further, the plating test conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution 40% glyoxylic acid solution

(3) pH adjusting agent KOH: 40 g water: an amount required to make the solution 1 L

The test results of the present comparative example are shown in Table 1.

The result of the thermal shock test for the full build using the plating solution of the present comparative example showed that the electric resistance was increased by 10% at 50 cycles, and therefore, the plating solution of the present comparative example was substantially inferior to that of the present invention. Further, as the result of the solder heating resistance test, cracks occurred in the plated film of corner portions of the through hole.

Form the results described above, the effect of adding succinic acid to the plating solution of the present invention could be verified.

Next, the case of applying the plating solution of the present comparative example to the seeding plating was studied by decreasing temperature of the plating solution to 30° C. The electroplating process and so on following to the seeding plating were performed according to the methods similarly to those of the embodiment 1. The results are shown in Table 1. The result of the thermal shock test for the full build using the plating solution of the present comparative example showed that the electric resistance was increased by 10% at 50 cycles, and therefore, the plating solution of the present comparative example was substantially inferior to that of the present invention. Further, as the result of the solder heating resistance test, cracks occurred in the plated film of corner portions of the through hole.

Form the results described above, in regard to the seeding plating, the effect of adding succinic acid to the plating solution of the present invention could be also verified.

[Comparative example 2]

In this comparative example, description will be made on a case where a large amount of succinic acid is added to the plating solution.

(Composition of the plating solution (Ib))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |
| succinic acid | 5 | g/L |

Therein, the concentration of potassium hydroxide is appropriately adjusted so as to satisfy the condition of pH=12.4. Further, the plating test conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution 40% glyoxylic acid solution

(3) pH adjusting agent KOH: 40 g water: an amount required to make the solution 1 L

The test results of the present comparative example are shown in Table 1.

The result of the thermal shock test for the full build using the plating solution of the present comparative example showed that the electric resistance was increased by 10% at 50 cycles, and therefore, the plating solution of the present comparative example was substantially inferior to that of the present invention. Further, as the result of the solder heating resistance test, cracks occurred in the plated film of corner portions of the through hole.

Form the results described above, it was clarified that there was an appropriate range in the amount of succinic acid added to the plating solution, and that the amount of 5 g/L was too much. Superiority of the present invention of setting the concentration of added succinic acid to 0.1 to 1000 ppm was verified.

Next, the case of applying the plating solution of the present comparative example to the seeding plating was studied by decreasing temperature of the plating solution to 30° C. The electroplating process and so on following to the seeding plating were performed according to the methods similarly to those of the embodiment 1. The results are shown in Table 1. The result of the thermal shock test for the full build using the plating solution of the present comparative example showed that the electric resistance was increased by 10% at 50 cycles, and therefore, the plating solution of the present comparative example was substantially inferior to that of the present invention. Further, as the result of the solder heating resistance test, cracks occurred in the plated film of corner portions of the through hole.

Form the results described above, it was clarified that in regard to the seeding plating, there was an appropriate range in the amount of succinic acid added to the plating solution, and that the amount of 5 g/L was too much. Superiority of the present invention of setting the concentration of added succinic acid to 0.1 to 1000 ppm was verified.

[Comparative example 3]

In this comparative example, description will be made on a case where an amount of succinic acid added to the plating solution is insufficient. The composition og the plating solution is as follows.

(Composition of the plating solution (Ic))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |
| succinic acid | 0.05 | mg/L |

Therein, the concentration of potassium hydroxide is appropriately adjusted so as to satisfy the condition of pH=12.4. Further, the plating test conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution 40% glyoxylic acid solution

(3) pH adjusting agent KOH: 40 g water: an amount required to make the solution 1 L

As described above, in the present comparative example, the amount of succinic acid added to the plating solution is as small as 0.05 mg.

The test results of the present comparative example are shown in Table 1.

The result of the thermal shock test for the full build using the plating solution of the present comparative example showed that the electric resistance was increased by 10% at 150 cycles, and therefore, the plating solution of the present comparative example was inferior to that of the present invention. That is, it cannot say that the board of the present comparative example has sufficient reliability as a wiring board. Further, in the result of the solder heating resistance test, cracks occurred in the plated film of corner portions of the through hole. However, the cracks were different from the cracks observed in the comparative examples 1 and 2, and were very small cracks which could be observed using an electron microscope with difficulty.

Form the results described above, superiority of the present invention of adding succinic acid to the plating solution was verified. Further, in regard to the amount of succinic acid added to the plating solution, the amount of 0.05 mg/L is too small, and it is preferably 0.1 mg/L or more.

Next, the case of applying the plating solution of the present comparative example to the seeding plating was studied by decreasing temperature of the plating solution to 30° C. The electroplating process and so on following to the seeding plating were performed according to the methods similarly to those of the embodiment 1. The results are shown in Table 1. The result of the thermal shock test for the full build using the plating solution of the present comparative example showed that the electric resistance was increased by 10% at 150 cycles, and therefore, the plating solution of the present comparative example was inferior to that of the present invention. Further, as the result of the solder heating resistance test, cracks occurred in the plated film of corner portions of the through hole. However, the cracks were smaller than the cracks observed in the comparative examples 1 and 2.

Form the results described above, in the case of the seeding plating, superiority of the present invention of adding succinic acid to the plating solution was verified. Further, in regard to the amount of succinic acid added to the plating solution, the amount of 0.05 mg/L is too small, and it is preferably 0.1 mg/L or more.

[Comparative example 4]

Description will be made below on a case where 1 g/L or more succinic acid is added to the plating solution.

(Composition of the plating solution (Id))

| | | |
|---|---|---|
| copper sulfide 5-hydrate | 0.04 | mol/L |
| ethylenediamin tetra-acetate | 0.1 | mol/L |
| glyoxylic acid | 0.03 | mol/L |
| potassium hydroxide | 0.01 | mol/L |
| 2,2′-bipyridyl | 0.0002 | mol/L |
| polyethylene glycol (average molecular weight 600) | 0.03 | mol/L |
| succinic acid | 1.5 | g/L |

Therein, the concentration of potassium hydroxide is appropriately adjusted so as to satisfy the condition of pH=12.4. Further, the plating test conditions are the same as the plating conditions according to the present invention (I) previously described.

<Supplemental solution>

(1) copper ion supplemental solution CuSO₄·5H₂O: 200 g water: an amount required to make the solution 1 L

(2) glyoxylic acid (copper ion reducing agent) supplemental solution 40% glyoxylic acid solution

(3) pH adjusting agent KOH: 40 g water: an amount required to make the solution 1 L

The test results of the present comparative example are shown in Table 1.

The result of the thermal shock test for the full build using the plating solution of the present comparative example showed that the electric resistance was increased by 10% at 150 cycles, and therefore, the plating solution of the present comparative example was inferior to that of the present invention. That is, it cannot say that the board of the present comparative example has sufficient reliability as a wiring board. Further, in the result of the solder heating resistance test, cracks occurred in the plated film of corner portions of the through hole. However, the cracks were different from the cracks observed in the comparative examples 1 and 2, and were very small cracks which could be observed using an electron microscope with difficulty.

Form the results described above, superiority of the present invention of adding succinic acid to the plating solution was verified. Further, in regard to the amount of succinic acid added to the plating solution, the amount of 1.5 g/L is too much, and it is preferably 1 g/L or less.

Next, the case of applying the plating solution of the present comparative example to the seeding plating was studied by decreasing temperature of the plating solution to 30° C. The electroplating process and so on following to the seeding plating were performed according to the methods similarly to those of the embodiment 1. The results are shown in Table 1. The result of the thermal shock test for the full build using the plating solution of the present comparative example showed that the electric resistance was increased by 10% at 150 cycles, and therefore, the plating solution of the present comparative example was inferior to that of the present invention. Further, as the result of the solder heating resistance test, cracks occurred in the plated film of corner portions of the through hole. However, the cracks were smaller than the cracks observed in the comparative examples 1 and 2.

Form the results described above, in the case of the seeding plating, superiority of the present invention of adding succinic acid to the plating solution was verified. Further, in regard to the amount of succinic acid added to the plating solution, the amount of 1.5 g/L is too much, and it is preferably 1 g/L or less.

TABLE 1

| | | | | | | | Full build | | Sending |
|---|---|---|---|---|---|---|---|---|---|
| | | | | | | Full build | plating | Seeding | plating |
| | | Number of | | | | plating | solder | plating | solder |
| | | repetitive | Plating | Plating | Ratio of | thermal | heating | thermal | heating |
| | Succinic acid concentration in | plating | temperature | rate | Cannizzaro | shock test | resistance | chock test | resistance |
| Item | plating solution (ppm) | processes | (° C. | (μm/h) | reaction | (∞) | test | (∞) | test |
| Embodiment 1 | 50 | 1 | 70 | 3.1 | 11.5% | 350 | good | — | — |
| Embodiment 2 | 50 | 1 | 30 | 1.2 | 6.5% | — | — | 300 | good |
| Embodiment 3 | 3 (1st init)-12 (1st end) | 1 | 70 | 3.2 | 13.2% | 350 | good | — | — |
| | 12 (2nd init)-20 (2nd end) | 2 | 70 | 3.2 | 12.2% | 350 | good | — | — |
| | 20 (3rd init)-29 (3rd end) | 3 | 70 | 3.2 | 11.6% | 350 | good | — | — |
| | 29 (4th init)-38 (4th end) | 4 | 70 | 3.2 | 11.5% | 350 | good | — | — |
| | 38 (4th init)-46 (5th end) | 5 | 70 | 3.2 | 11.0% | 350 | good | — | — |
| | 46 (6th init)-56 (6th end) | 6 | 70 | 3.2 | 10.5% | 350 | good | — | — |
| Embodiment 4 | 0.1 (1st init)-0.7 (1st end) | 1 | 70 | 3.1 | 15.0% | 350 | good | — | — |
| | 0.7 (2nd init)-1.5 (2nd end) | 2 | 70 | 3.2 | 14.5% | 350 | good | — | — |
| | 1.5 (3rd init)-2.1 (3rd end) | 3 | 70 | 3.2 | 14.3% | 350 | good | — | — |
| | 2.1 (4th init)-2.7 (4th end) | 4 | 70 | 3.1 | 13.0% | 350 | good | — | — |
| | 2.7 (5th init)-3.3 (5th end) | 5 | 26 | 3.1 | 12.0% | 350 | good | — | — |
| Embodiment 5 | 50 (1st init)-210 (1st end) | 1 | 70 | 3.2 | 11.0% | 350 | good | — | — |
| | 210 (2nd init)-360 (2nd end) | 2 | 70 | 3.2 | 10.0% | 350 | good | — | — |
| | 360 (3rd init)-515 (3rd end) | 3 | 70 | 3.1 | 9.5% | 350 | good | — | — |
| | 515 (4th init)-660 (4th end) | 4 | 70 | 3.2 | 9.2% | 350 | good | — | — |
| | 650 (5th init)-825 (5th end) | 5 | 70 | 3.2 | 8.5% | 350 | good | — | — |
| | 825 (6th init)-985 (6th and) | 6 | 70 | 3.1 | 6.2% | 350 | Good | — | — |
| Embodiment 6 | 1.6 | — | 28 | 1.1 | 8.5% | — | — | 300 | good |
| | 20 | — | 30 | 1.2 | 6.5% | — | — | 300 | good |
| | 150 | — | 25 | 1.1 | 5.5% | — | — | 300 | good |
| | 600 | — | 28 | 1.1 | 3.5% | — | — | 300 | good |
| | 1000 | — | 30 | 1.2 | 3.2% | — | — | 300 | good |
| Comparative 1 | 0 | 1 | | 3.0 | 21.0% | 50 | no good | — | — |
| Comparative 2 | 5000 (5 g/L) | 1 | | 3.1 | 6.1% | 50 | no good | — | — |
| Comparative 3 | 0.05 | 1 | | 3.1 | 20.0% | 150 | no good | — | — |
| Comparative 4 | 1500 (1.5 g/L) | 1 | | 3.1 | 4.8% | 150 | no good | — | — |

According to the present invention, by adding succinic acid to the electroless copper plating solution containing glyoxylic acid as the reducing agent, it is possible to provide the electroless copper plating solution having an excellent property of uniformly depositing copper plating to a through hole in a wiring board, and further to provide a wiring board having good connection reliability of a through hole.

What is claimed is:

1. An electroless copper plating solution including copper ions; a complexing agent of copper ion; a copper ion reducing agent containing glyoxylic acid or a salt of glyoxylic acid; a pH adjusting agent; and succinic acid.

2. A supplementary solution for an electroless copper plating solution including a copper ion reducing agent containing glyoxylic acid or a salt of glyoxylic acid; and succinic acid of 10 to 500 ppm.

3. An electroless copper plating method of forming a copper film on a surface of a board by an electroless copper plating solution including copper ions; a complexing agent of copper ion; a copper ion reducing agent containing glyoxylic acid or a salt of glyoxylic acid; a pH adjusting agent; and succinic acid.

4. An electroless copper plating method, wherein the supplementary solution for an electroless copper plating method according to claim 2 is supplied.

5. A method of manufacturing a wiring board, wherein a conductor circuit is formed on a surface of a board by an electroless copper plating solution including copper ions; a complexing agent of copper ion; a copper ion reducing agent containing glyoxylic acid or a salt of glyoxylic acid; a pH adjusting agent; and succinic acid.

6. A method of forming a wiring board, the method comprising the steps of:
forming a through hole in a copper-clad laminate having a laminated copper film on a surface of at least one side of main faces of a board;
adding a catalyst onto an inner wall surface of said through hole;
forming a copper film in said through hole of the board formed in the above step by performing an electroless copper plating using an electroless copper plating solution including copper ions, a complexing agent of copper ion, a copper ion reducing agent containing glyoxylic acid or a salt of glyoxylic acid, a pH adjusting agent and succinic acid;
forming an etching resist over the whole surface of said board obtained in the above step, and forming an etching resist wiring pattern by an exposing and developing process; and
forming a copper film wiring pattern by dissolving and removing the exposed copper film in the above step.

7. A method of forming a wiring board, the method comprising the steps of:
forming a through hole in a copper-clad laminate having a laminated copper film on a surface of at least one side of main faces of a board;
adding a catalyst onto an inner wall surface of said through hole;
forming a copper film in said through hole of the board formed in the above step by performing an electroless copper plating using an electroless copper plating solution including copper ions, a complexing agent of copper ion, a copper ion reducing agent containing glyoxylic acid or a salt of glyoxylic acid, a pH adjusting agent and succinic acid of 10 to 500 ppm;
forming an etching resist over the whole surface of said board obtained in the above step, and forming an etching resist wiring pattern by an exposing and developing process; and
forming a copper film wiring pattern by dissolving and removing the exposed copper film in the above step.

8. A method of forming a wiring board, the method comprising the steps of:
forming a through hole in a double-sided copper-clad laminate;
adding a catalyst onto an inner wall surface of said through hole using a sensitization processing agent and an adhesion promotion processing agent;
forming a copper film in said through hole of the board formed in the above step by performing an electroless copper plating using an electroless copper plating solution including copper ions, a complexing agent of copper ion, a copper ion reducing agent containing glyoxylic acid or a salt of glyoxylic acid, a pH adjusting agent and succinic acid;
forming an etching resist of a photosensitive dry-film type over the whole surface of said board obtained in the above step, and forming an etching resist wiring pattern by an exposing and developing process; and
forming a copper film wiring pattern by dissolving and removing the exposed copper film in the above step.

9. A method of forming a wiring board, the method comprising the steps of:
forming a through hole in a copper-clad laminate having a laminated copper film on a surface of at least one side of main faces of a base material;
adding a catalyst onto an inner wall surface of said through hole;
forming a copper film in said through hole of the board formed in the above step by performing an electroless copper plating while a supplementary solution for an electroless copper plating solution including a copper ion reducing agent containing glyoxylic acid or a salt of glyoxylic acid and succinic acid of 10 to 500 ppm is being supplied to an electroless copper plating solution including copper ions, a complexing agent of copper ion, a copper ion reducing agent containing glyoxylic acid or a salt of glyoxylic acid, a pH adjusting agent and succinic acid;
forming an etching resist over the whole surface of said board obtained in the above step, and forming an etching resist wiring pattern by an exposing and developing process; and
forming a copper film wiring pattern by dissolving and removing the exposed copper film in the above step.

10. A method of forming a wiring board, the method comprising the steps of:
forming a through hole in a double-sided copper-clad laminate;
adding a catalyst onto an inner wall surface of said through hole using a sensitization processing agent and a adhesion promotion processing agent;
forming a copper film in said through hole of the board formed in the above step by performing an electroless copper plating while a supplementary solution for an electroless copper plating solution including a copper ion reducing agent containing glyoxylic acid or a salt of glyoxylic acid and succinic acid of 10 to 500 ppm is being supplied to an electroless copper plating solution including copper ions, a complexing agent of copper ion, a copper ion reducing agent containing glyoxylic acid or a salt of glyoxylic acid, a pH adjusting agent and succinic acid;
forming an etching resist of a photosensitive dry-film type over the whole surface of said board obtained in the above step, and forming an etching resist wiring pattern by an exposing and developing process; and
forming a copper film wiring pattern by dissolving and removing the exposed copper film in the above step.

11. A method of manufacturing a wiring board, the method comprising the steps of:
forming a copper film on a surface of a board using an electroless copper plating solution including a copper ion reducing agent, a pH adjusting agent and succinic acid; and then
performing electroplating using said copper film as an electric power supply film.

12. A method of manufacturing a wiring board, the method comprising the steps of:
forming a copper film on a surface of a board while a supplementary solution for an electroless copper plating solution including a copper ion reducing agent containing glyoxylic acid or a salt of glyoxylic acid and succinic acid of 10 to 500 ppm is being supplied to an electroless copper plating solution including a copper ion reducing agent, a pH adjusting agent and succinic acid; and then
performing electroplating using said copper film as an electric power supply film.
